(19) United States
(12) Patent Application Publication
(10) Pub. No.: US 2014/0029196 A1
(43) Pub. Date: Jan. 30, 2014

(54) SYSTEM FOR BALANCED POWER AND THERMAL MANAGEMENT OF MISSION CRITICAL ENVIRONMENTS

(71) Applicant: Kevin Smith, Niles, MI (US)

(72) Inventor: Kevin Smith, Niles, MI (US)

(21) Appl. No.: 14/111,891

(22) PCT Filed: Apr. 16, 2012
(86) PCT No.: PCT/US12/33842

§ 371 Date: Oct. 15, 2013

Related U.S. Application Data
(60) Provisional application No. 61/475,696, filed on Apr. 15, 2011.

(51) Int. Cl. H05K 7/20

(52) U.S. Cl. CPC H05K 7/20763
USPC 361/679.53; 361/679.46; 361/699

(57) ABSTRACT

Data center capsules providing modular and scalable capacity with integrated power and thermal transmission capabilities. Modular integrated central power system (“ICPS”) to fulfill the power and thermal needs of data center environments or other mission critical environments. Computer-based systems and methods for controlling the energy- and thermal-envelope of any single data center environment or other mission critical environment, or an ecosystem of multiple data center environments or multiple other mission critical environments.

### RELATED APPLICATION

This application claims the priority benefit of U.S. Patent Application Ser. No. 61/475,696, the disclosure of which is incorporated herein in its entirety.

### BACKGROUND

The traditional brick and mortar data center has offered a secure environment where Information Technology (“IT”) operations of organizations are housed and managed on a 24×7×365 basis. Typically assets contained within a data center include interconnected servers, storage, and other devices that perform computations, monitor and coordinate information, and communicate with other devices both within the data center and without. A modern, comprehensive data center offers services such as 1) hosting; 2) managed services; and 3) bandwidth leasing, along with other value-added services such as mirroring data across multiple data centers and disaster recovery. “Hosting” includes both co-location, in which different customers share the same infrastructure such as cabinets and power, and dedicated hosting, where a customer leases or rents space dedicated to their equipment, “Managed services” may include networking services, security, system management support, managed storage, content delivery, managed hosting, and application hosting, and many others.

Today the infrastructure to support these activities is designed, manufactured, and installed as independent systems engineered to work together in a custom configuration, which may include 1) security systems providing restricted access to data center and power system environments; 2) earthquake and flood-resistant infrastructure for protection of equipment and data; 3) mandatory power backup facilities including. Uninterruptible Power Supplies (“UPS”) and standby generators; 4) thermal systems including chillers, cooling towers, cooling coils, water loops, air handlers, computer room air conditioning (“CRAC”) units, etc.; 5) fire protection/suppression devices; and 6) high bandwidth fiber optic connectivity. Collectively, these systems comprise the infrastructure necessary to operate a modern day data center facility.

The dramatic increases over the last decade or so in both the size of the data center user base and, just as importantly, the quantity of content (i.e., data) created per user have generated a demand for improved storage capacity, increased bandwidth, faster transmission, and lower operating cost. The pace of this expansion is showing no sign of slowing. Finding sufficient power and cooling to meet the increasing demand have risen to become the fundamental challenges facing data center industry.

From the power management side, one of the key measures driving the data center industry is to improve its power usage effectiveness (“PUE”). PUE is the measure of how efficiently a computer data center utilizes its power. PUE is determined by dividing the amount of power entering a data center by the power used to run the computer infrastructure contained within it. The more efficiently a data center operation can manage and balance power usage in the data center, the lower the PUE. It is generally understood that as PUE approaches one (1.0) the compute environment is increasingly efficient, enabling one (1.0) unit of energy to be turned into one (1.0) unit of compute capacity.

Another issue is the increased power requirements of modern computing equipment, which requires increased cooling. The typical power load per square foot within a typical data center is between 100-300 watts/sq. ft. Naturally, as the power density increases there is a corresponding increase in the heat density and thus the cooling required. Many new technologies, such as blade servers, push power requirements well past 300 watts per square foot, forcing a major emphasis on balancing the thermal load within the system. An important relationship between power input into the computing devices within the data center and the overall thermal load that exists within any data center environment. Approximately one ton of cooling must be provided for every 3,517 kilowatts (KWs) of power consumed by the computing devices. Absent critical innovation for decreasing PUE, and as the data center industry continues to grow; the critical loads, the total facility load, and local energy generation will not only be expensive for the data center and its customers, it will also severely tax the existing energy infrastructure.

To date, the majority of those seeking technical innovation to gain efficiencies in the data center have focused on the constituent elements of the facility systems rather than on the system as a whole. This is in stark contrast to the fact that every data center is traditionally a custom-built installation of various components; thus, the highest level of optimization possible is generally at the individual component level. In such a situation a holistic energy envelope and thermal management solution is extremely complicated and difficult to achieve. A comprehensive solution that improves the energy efficiency of the entire system will provide significant advantages over the prior art.

### SUMMARY

The present disclosure includes disclosure of data center capsules. In at least one embodiment, a data center capsule according to the present disclosure provides modular and scalable computing capacity. In at least one embodiment, a data center capsule according to the present disclosure comprises a first data center module, the first data center module comprising a cooling system and an electrical system. In at least one embodiment, a data center capsule according to the present disclosure comprises a data network. In at least one embodiment, a data center capsule according to the present disclosure comprises a cooling system comprising a pre-cooling system and a post-cooling system. In at least one embodiment, a data center capsule according to the present disclosure comprises a second data center module, the second data center module comprising a cooling system and an electrical system. In at least one embodiment, a data center capsule according to the present disclosure comprises a second data center module that comprises a data network. In at least one embodiment, a data center capsule according to the present disclosure comprises a first data center module joined to a second data center module. In at least one embodiment, a data center capsule according to the present disclosure comprises a first data center module and a second data center module joined air-tightly. In at least one embodiment, a data center capsule according to the present disclosure comprises a first data center module and a second data center module joined water-tightly. In at least one embodiment, a data center capsule according to the present disclosure, a first data center module's cooling system is coupled to a second data center module's cooling system. In at least one embodiment, a data center capsule according to the present disclosure a first data center module's electrical system is coupled to a second data center module's electrical system. In at least one embodiment, a data center capsule according to the present disclosure a first data center module comprises a data network, and wherein the first data center module's data network is coupled to the second data center module's data network. In at least one embodiment, a data center capsule according to the present disclosure comprises an integrated docking device. In at least one embodiment, a data center capsule according to the present disclosure comprises an integrated docking device configured to connect a first data center module to a source of electricity. In at least one embodiment, a data center capsule according to the present disclosure comprises an integrated docking device configured to connect a first data center module to a source of chilled water. In at least one embodiment, a data center capsule according to the present disclosure comprises an integrated docking device configured to connect a first data center module to an external data network.

The present disclosure includes disclosure of modular power system. In at least one embodiment, a modular power system according to the present disclosure comprises power distribution circuitry; fiber optic data cable circuitry; and chilled water plumbing. In at least one embodiment, a modular power system according to the present disclosure comprises redundant power distribution circuitry. In at least one embodiment, a modular power system according to the present disclosure comprises redundant fiber optic data cable circuitry. In at least one embodiment, a modular power system according to the present disclosure comprises an energy selection device capable of switching between multiple electric energy sources, as needed within one quarter cycle. In at least one embodiment, a modular power system according to the present disclosure comprises power distribution circuitry capable of receiving an input voltage of at least 12,470 volts. In at least one embodiment, a modular power system according to the present disclosure comprises a step-down transformation system that converts an input voltage of at least 12,470 volts to an output voltage of 208 volts or 480 volts. In at least one embodiment, a modular power system according to the present disclosure comprises a water chilling plant. In at least one embodiment, a modular power system according to the present disclosure comprises a water chilling plant equipped with a series of frictionless, oil free magnetic bearing compressors arranged in an N+1 configuration and sized to handle the cooling needs of the facility. In at least one embodiment, a modular power system according to the present disclosure comprises a thermal storage facility that stores excess thermal capacity in the form of ice or water, the thermal storage facility being equipped with a glycol cooling exchange loop, a heat exchanger, and ice producing chiller plant or comparable ice-producing alternative. In at least one embodiment, a modular power system according to the present disclosure comprises a system of cooling loops, which may comprise multi-path chilled water loops, a glycol loop for the ice storage system, and a multi-path cooling tower water loop. In at least one embodiment, a modular power system according to the present disclosure comprises an economizer heat exchanger between the tower and chilled water loops. In at least one embodiment, a modular power system according to the present disclosure comprises a thermal input selection device. In at least one embodiment, a modular power system according to the present disclosure comprises a thermal input selection device comprising a three-way mixing value for mixing of hot and cold water from the system water storage/distribution tanks. In at least one embodiment, a modular power system according to the present disclosure comprises a heat recovery system comprising a primary water loop, the heat recovery system providing pre-cooling and heat reclamation. In at least one embodiment, a modular power system according to the present disclosure comprises a plurality of cooling towers arranged in an N+1 configuration.

The present disclosure includes disclosure of computer-based systems and methods for controlling the energy- and/or thermal-envelope of a single data center environment or an ecosystem of multiple data center environments. The present disclosure includes disclosure of computer-based systems for analyzing the energy- and/or thermal-envelope of a single data center environment or an ecosystem of multiple data center environments. The present disclosure includes disclosure of computer-based systems for analyzing the energy- and/or thermal-envelope of a single data center environment or an ecosystem of multiple data center environments, the systems comprising a neural network. The present disclosure includes disclosure of computer-based systems for analyzing the energy- and/or thermal-envelope of a single data center environment or an ecosystem of multiple data center environments, the systems comprising artificial intelligence. The present disclosure includes disclosure of methods for analyzing the energy- and/or thermal-envelope of a data center environment or an ecosystem of multiple data center environments, the methods comprising the step of collecting data from an energy envelope, including generation, transmission, distribution, and consumption data. The present disclosure includes disclosure of methods for analyzing the energy- and/or thermal-envelope of a data center environment or an ecosystem of multiple data center environments, the methods comprising the step of selectively optimizing availability, reliability, physics, economics, and/or carbon footprint. The present disclosure includes disclosure of methods for analyzing the energy- and/or thermal-envelope of a data center environment or an ecosystem of multiple data center environments, the methods comprising the step of collecting information such as ambient air temperature, relative humidity, wind speed or other environmental factors, power purchase rates, transmission or distribution power quality, and/or central plant water temperature. The present disclosure includes disclosure of methods for analyzing the energy- and/or thermal-envelope of a data center environment or an ecosystem of multiple data center environments, the methods comprising the step of collecting information such as cooling system fan speeds, air pressure and temperature. The present disclosure includes disclosure of computer-based systems for management of a single data center environment or an ecosystem of multiple data center environments, the systems configured to communicate with building control systems, including OBIX, BacNET, Modbus, Lon, and the like, along with new and emerging energy measurement standards. The present disclosure includes disclosure of computer-based systems for management of a single data center environment or an ecosystem of multiple data center environments, the systems comprising an open, layered architecture utilizing standard protocols. The present disclosure includes disclosure of computer-based systems for management of a single data center environment or an ecosystem of multiple data center environments, the systems configured to use advanced storage and analysis techniques, along with specialized languages to facilitate performance and reliability. The present disclosure includes disclosure of computer-based systems for analyzing the energy- and/or thermal-envelope of a single data center environment or an ecosystem of multiple data center environments, the systems configured to make use of various forms of data mining, machine learning techniques, and artificial intelligence to utilize data for real time control and human analysis. The present disclosure includes disclosure of computer-based systems for analyzing the energy- and/or thermal-envelope of a single data center environment or an ecosystem of multiple data center environments, the systems configured to allow longitudinal analysis across multiple data sets. The present disclosure includes disclosure of computer-based systems configured to allow longitudinal analysis across multiple data sets, wherein the data sets include but are not limited to local building information or information from local data center capsules and external data sets including but not limited to weather data, national electrical grid data, carbon emission surveys, USGS survey data, seismic surveys, astronomical, or other data sets collected on natural phenomenon or other sources. The present disclosure includes disclosure of computer-based systems for analyzing the energy- and/or thermal-envelope of a single data center environment or an ecosystem of multiple data center environments, the systems configured to produce research grade data. The present disclosure includes disclosure of computer-based systems for analyzing the energy- and/or thermal-envelope of a single data center environment or an ecosystem of multiple data center environments, the systems configured to dynamically model an integrated central power system, a transmission system, and/or a data center capsule.

The present disclosure includes disclosure of computer-based systems. The present disclosure includes disclosure of computer-based systems for analyzing the energy- and/or thermal-envelope of a single data center environment or an ecosystem of multiple data center environments, the systems configured to interpret economic and financial data, including, but not limited to the current rate per kilowatt-hour of electricity and cost per therm of natural gas. The present disclosure includes disclosure of computer-based systems for analyzing the energy- and/or thermal-envelope of a single data center environment or an ecosystem of multiple data center environments, the systems configured to aggregate diverse data sets and draw correlations between the various data from the diverse systems and locations

### BRIEF DESCRIPTION OF THE DRAWINGS

The features and advantages of this disclosure, and the manner of attaining them, will be more apparent and better understood by reference to the following descriptions of the disclosed methods and systems, taken in conjunction with the accompanying drawings, wherein:

FIG. 1 shows a block diagram of a system for balanced power and thermal management of mission critical environments in accordance with at least one embodiment of the present disclosure;

FIG. 2 shows a block diagram of an integrated central power system in accordance with at least one embodiment of the present disclosure;

FIG. 3 shows a block diagram of the thermal management components of a modular integrated central power system in accordance with at least one embodiment of the present disclosure;

FIG. 4 shows a perspective view of a data center capsule according to at least one embodiment of the present disclosure;

FIG. 5 shows a partially exploded perspective view of a data center capsule according to at least one embodiment of the present disclosure;

FIG. 6 shows a partially cutaway perspective view of a data center capsule according to at least one embodiment of the present disclosure;

FIG. 7 shows a partially cutaway perspective view of a data center capsule according to at least one embodiment of the present disclosure;

FIG. 8 shows a cutaway elevation view of data center capsule according to at least one embodiment of the present disclosure; and

FIG. 9 shows a cutaway elevation view of data center capsule according to at least one embodiment of the present disclosure.

FIG. 10 shows a flowchart illustration the operation of a global energy operating system according to at least one embodiment of the present disclosure.

### DESCRIPTION

For the purposes of promoting an understanding of the principles of the present disclosure, reference will now be made to the embodiments illustrated in the drawings, and specific language will be used to describe the same. It will nevertheless be understood that no limitation of the scope of this disclosure is thereby intended.

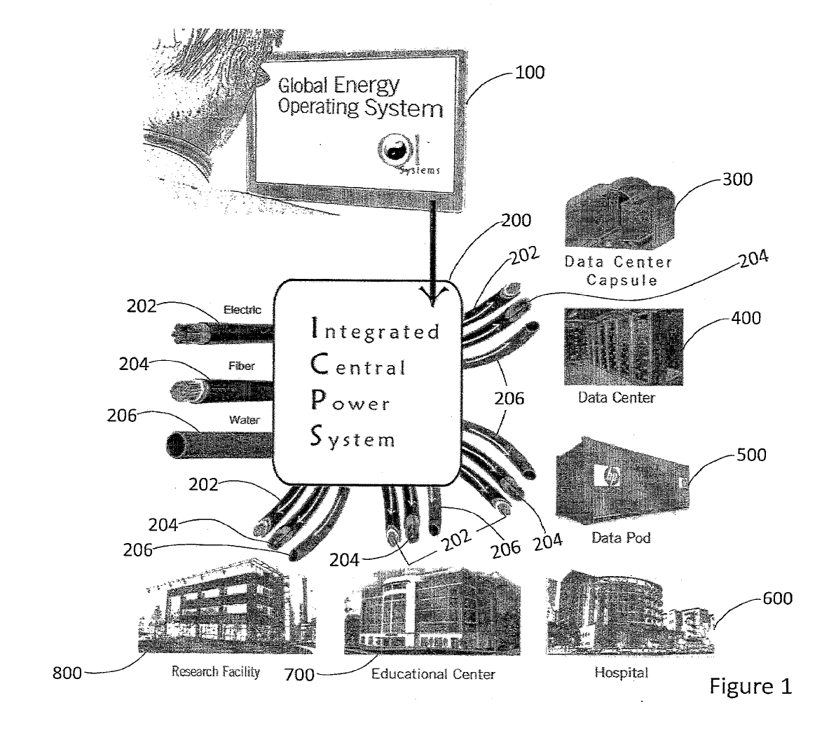

The present disclosure includes disclosure of systems and methods for balanced power and thermal management of mission critical environments. FIG. 1 shows a block diagram of a system 10 for balanced power and thermal management of mission critical environments, in accordance with at least one embodiment of the present disclosure. Shown in FIG. 1 are Global Energy Operating System (“GEOS”) 100, which is electronically interconnected with Integrated central power system (“ICPS”) 200. As discussed in more detail hereinafter, ICPS 200 delivers one or more electric services 202, fiber optic (or copper) data services 204, and cooling services 206 to one or more mission critical environments such as, for example, data center capsules 300 of the present disclosure. In addition to, or in lieu of data center capsules 300, ICPS 200 delivers one or more electric services 202, fiber optic (or copper) data services 204, and cooling services 206 to traditional brick and mortar data centers 400, data pods 500, hospitals 600, educational centers 700, and/or research facilities 800.

In at least one embodiment of the present disclosure, such a system 10 includes a modular ICPS 200 to address the power and thermal needs of mission critical environments, a data center capsule 300 providing modular and scalable compute capacity, and a GEOS 100, which serves as the master controller of the energy envelope of any single mission critical environment or an ecosystem of multiple mission critical environments. In at least one embodiment, the ICPS 200 and the data center capsules 300 according to embodiments of the present disclosure are designed to provide a flexible, modular, and scalable approach utilizing manufactured components rather than traditional, custom configurations typical of the brick and mortar data center.

This modular approach for systems according to the present disclosure incorporates the ICPS 200, data center capsule 300, and GEOS 100 into a framework that can be deployed in a variety of environments including, but not limited to dispersed computing parks, hospitals, research parks, existing data centers, purpose-built buildings, and warehouse configurations. Networking these elements across individual or multiple energy ecosystems supplies GEOS 100 with data that may be analyzed and utilized to coordinate electrical, thermal, and security systems. In at least one embodiment, GEOS 100 is configured to constantly evaluate the most economical means of operation through monitoring of real-time utility market prices. Though the focus of this disclosure will be on the individual elements, the overall system according to at least one embodiment of the present disclosure could be advantageously deployed as a complete end-to-end solution.

According to at least one embodiment of an ICPS 200 according to the present disclosure, the thermal and electrical systems are housed in a modular facility separate and apart from any permanent physical structure. According to at least one embodiment, an ICPS 200 according to the present disclosure is constructed from modular components that can be coupled together as needed. An ICPS 200 according to at least one embodiment of the present disclosure is able to receive power at 12,470V or 13,800V for transmission efficiency and distribute it at operating voltages. An ICPS 200 according to at least one embodiment of the present disclosure is able to remove thermal energy via water or other fluid in order to benefit from the inherent thermal mass and efficiency of such substances.

In at least one embodiment of the present disclosure, an ICPS 200 forms the center of a hub and spoke arrangement of an ICPS 200 and data centers or other mission critical facilities. By utilizing power and cooling from an ICPS 200, a data center or other mission critical facility no longer has to dedicate internal space for sizable, expensive thermal management equipment or electrical equipment associated with distribution of high voltage power through a building. Instead, the data center operator has to make room only for the computing devices themselves, along with utility lines. Since as much as 60% of the total floor space of a data center typically is dedicated to housing the supporting infrastructure that drives the electrical and thermal management capacity of a data center, this change alone greatly reduces the cost to build and operate data centers.

In addition to more efficient use of space, through the use of as ICPS 200 according to the present disclosure, the data center environment is no longer restricted to purpose built facilities. This makes planning for expansion much easier, especially if the computing devices are housed within the data center capsule 300 disclosed herein, or any other containerized system, which could be housed outside or within a traditional building shell. Because the ICPS 200 systems according to the present disclosure are modular, the risk to a data center is decreased. To increase data center capacity, the operator simply has to add additional ICPS 200 modules to increase power and thermal management capacity.

### Integrated Central Power System

The integrated central power system 200 according to the present disclosure is based upon the premise of providing a balanced energy source, which is modular in nature, and works with the global energy operating system 100 to manage electrical and thermal load. In at least one embodiment, such a system comprises multiple power sources as energy inputs.

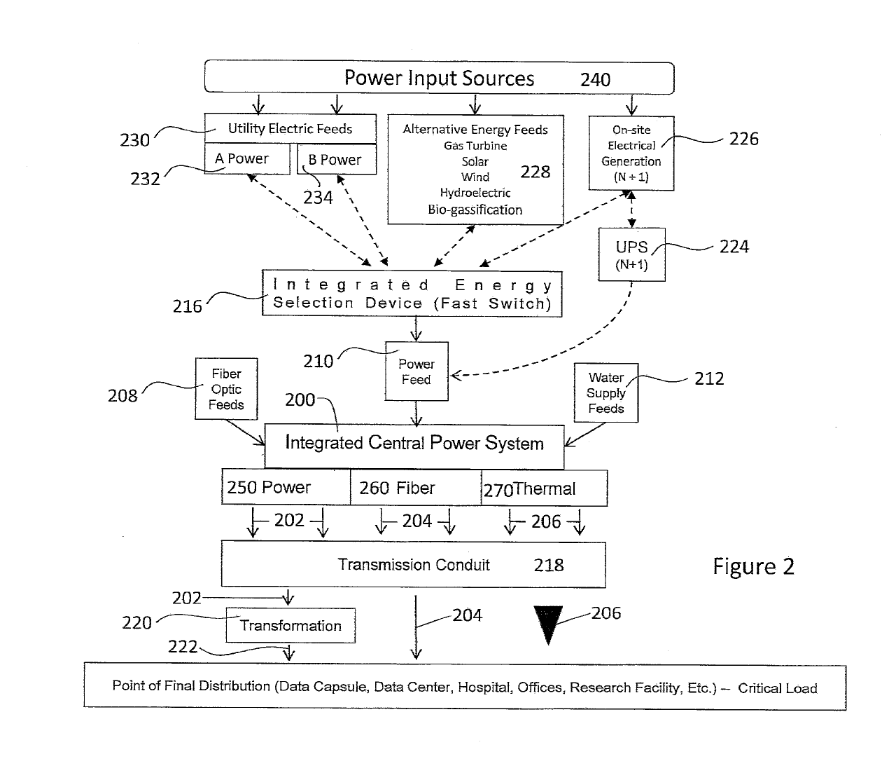

FIG. 2 shows a block diagram of an integrated central power system 200 in accordance with at least one embodiment of the present disclosure. As shown in FIG. 2, ICPS 200 comprises power components 250, fiber optic (data) components 260, and thermal components 270. In the embodiment shown in FIG. 2, ICPS 200 received fiber optic feed 208, power feed 210, water supply feeds 212.

In at least one embodiment of the present disclosure, ICPS 200 is able to receive power from a plurality of sources, including from one or more electric utilities 230 (such as utility A 232 and utility B 234), alternative energy sources 228, and onsite power generation 226 (which may include uninterruptible power supply 224). Onsite electrical generation 226, alternative energy feeds 228, and utility electric feeds 230 feed into IESD 216.

The output of ICPS 200 comprises electrical output 202, data output 204, and thermal output 206. In at least one embodiment of the present disclosure, each is routed through a transmission conduit 218 to the final point of distribution. In at least one embodiment of the present disclosure, electrical output 202 is transformed by transformer device 220 into a different voltage output 222.

According to at least one embodiment of the present disclosure, a modular ICPS 200 includes, but is not limited to, 1) a modular design which addresses the power and thermal needs of mission critical environments while separating these elements from the physical structure of the critical environment; 2) a minimum of three incoming local utility feeds into the ICPS 200, which include but are not limited to water utility connections, redundant electrical sources connected at distribution voltage (12,470V or 13,800V) on dedicated feeders from utility substations, and redundant fiber optic cable feeds; 3) an integrated energy selection device (“IESD”) capable of dynamically switching between multiple electric energy sources as needed within one quarter cycle; 4) an electrical bridge device, which in one embodiment could be an uninterruptible power supply (“UPS”) solution that is scalable between 2 MW-20 MW and could be deployed in a modular configuration to achieve up to 200 MW power densities; 5) a series of on-site electrical generators that are sized appropriately to the needs of the ICPS 200; 6) a step-down electrical transformer system that converts 12,470V or 13,800V input voltage to 208V or 480V (as necessary) output voltage at the point of final distribution; 7) a water chilling plant equipped, in at least one embodiment, with a series of frictionless, oil free magnetic bearing compressors arranged in an N+1 configuration and sized to handle the cooling needs of the mission critical facility; 8) a thermal storage facility that stores excess thermal capacity in the form of ice or water and is equipped, in at least one embodiment, with a glycol cooling exchange loop, a heat exchanger, and ice producing chiller plant or comparable ice-producing alternative; 9) a system of cooling loops, which in at least one embodiment include but may not be limited to, multi-path chilled water loops, a glycol loop for the ice storage system, and a multi-path cooling tower water loop; 10) an economizer heat exchanger between the tower and chilled water loops; 11) a thermal input selection device, which in one embodiment may be a three-way mixing value, providing for mixing of hot and cold water from the system water storage/distribution tanks; 11) a heat recovery system with a water loop providing pre-cooling and heat reclamation coupled to the critical load cooling equipment; 13) a series of cooling towers arranged in an N+1 configuration tied to the cooling tower water loop; and 14) an integrated security and monitoring system cable of being controlled by the automation system(s) and GEES 100.

Although a variety of configurations are possible, in at least one embodiment a system comprising an ICPS 200 is arranged in a hub and spoke model. The spokes of this system are achieved by placing the aforementioned transmission elements (i.e. electric, cooling loops, and fiber) into at least one large diameter conduit per spoke that radiates out from the ICPS 200 (as the hub) to the point of final distribution which could be any mission critical facility, such as a data center capsule 300, an existing brick-and-mortar data center 400, a containerized compute environment 500, a hospital 600, an educational facility 700, a research facility 800, or any other entity requiring balanced electrical and thermal capabilities to support their computing resources.

### Balanced System of Electric and Thermal Sources

Core to the design of a system according to at least one embodiment of the present disclosure comprising GEOS 100 and ICPS 200, is a mechanical, electrical, and electronic systems that balance electric and thermal sources and uses. A system according to at least one embodiment of the present disclosure comprising GEOS 100 and ICPS 200 is capable of managing multiple electric and thermal energy sources which are selectable depending upon factors including but not limited to availability, reliability, physics, economics, and carbon footprint.

In at least one embodiment, an ICPS 200 according to the present disclosure is equipped with redundant power feeds from at least one utility substation connected at 12,470V and/or 13,800V distribution voltage. Transmission at a distribution voltages such as 12,470V and/or 13,800V creates minimal loss in efficiency along the transmission line from the substations to the ICPS 200. For the same reason, in at least one embodiment of an ICPS 200 similar voltages will be used to convey power from the ICPS 200 to the final distribution point where immediately before use, step-down transformers convert the 12,470V or 13,800V feed to 208V/480V. According to at least one embodiment, there is a direct connection from the ICPS 200 to the substation with no additional customers tapping into the line, providing for a more reliable power solution and enabling the substation-ICPS 200 interface to become a more valuable control point for the utility company or power generation site.

In at least one embodiment, the ICPS 200 can integrate multiple energy feeds. Along with standard electrical utility feeds from the national grid, power could be received from a number of other power generation sources including, but not limited to local generation from sources such as, diesel generators, wind power, photovoltaic cells, solar thermal collectors, bio-gassification facilities, conversion of natural gas to hydrogen, steam methane reformation, hydrogen generation through electrolysis, hydroelectric, nuclear, gas turbine facilities, and/or other cogeneration facilities. Through this approach, the reliability of the ICPS 200 is greatly enhanced and the data center operator can make use of the most economical power available on-demand. In addition, it would increase the value of the data center to the utilities because it has the ability to shave its load instantaneously. Switching between these main power sources is accomplished through the IESD 216 of ICPS 200, which is comprised of a fast switch capable of dynamically switching between main power feeds within one quarter cycle, An IESD according to at least one embodiment of the present disclosure enables selective utilization of a variety of energy sources as needed based on economic modeling of power utilization and/or direct price signaling from the utilities. As electrical energy storage becomes increasingly viable, the ICPS 200 could shift energy sources based on modeling energy storage capabilities in a similar manner to the way thermal storage is done now.

An ICPS 200 according to at least one embodiment of the preset disclosure will have an ability to scale by adding additional manufactured modules of electrical bridging systems, such as, for example, UPS systems. In at least one embodiment, the PureWave UPS system manufactured by S&C Electric Company could be used to provide medium-voltage UPS protection in an W1 configuration. As an example, such a system could be deployed in an initial rating of 5.0 MVA/4.0 MW (N+1) at 12,470V and expandable to 12,5 MVA/10 MW (N+1) in 2.5 MVA/2.0 MW chunks, with redundancy provided at the level of 2.5 MVA/2.0 MW UPS energy storage container. With this type of manufactured solution, the ICPS concept according to the present disclosure is stackable up to a power density of 200 MW through the deployment of multiple ICPSs 200. In addition to one or more ICPSs 200, back-up generators (diesel, natural gas, etc.) or hydrogen fuel cells could be sized to the needs of the facility. In at least one embodiment, such generators could be deployed in an N+1 configuration.

Following distribution to the mission critical environment at high potential (12,470V and/or 13,800V), in at least one embodiment of the present disclosure the power is stepped down through a transformer to meet the needs of the terminal equipment, typically 208V/480V. The consumers of this stepped down power could include a data center capsule 300, an existing brick-and-mortar data center 400, a containerized compute environment 500, a hospital 600, an educational center 700, a research facility 800, or any other facility requiring balanced electrical and thermal capabilities to support their resources.

The integrated design of the ICPS 200 according to the present disclosure is a core element to its functional capabilities, reflected in the integration of both electrical power and thermal systems into a unified plant. In at least one embodiment of the present disclosure, an ICPS 200 is capable of thermal source selection to produce an improved result through selection and integration of multiple discrete thermal management systems, such as, for example, chillers, cogeneration systems (CCHP), ice storage, cooling towers, closed loop heat exchanger, rain water collection systems for make up water, geothermal, and the like. An ICPS 200 according to at least one embodiment of the present disclosure comprises a series of frictionless, oil-free magnetic bearing compressor chillers or a similarly reliable, high efficiency chiller system arranged in an N+1 configuration and sized to handle the thermal requirements of the facilities connected to the ICPS 200. These chillers provide the cooling loops and the cooling fluid necessary to remove heat from the mission critical environments.

In at least one embodiment of the present disclosure, such chillers also serve as the source for an ice production and storage facility that is sized to meet the needs of thermal mitigation. Such an ice storage facility in at least one embodiment of the present disclosure is equipped with a closed-loop glycol cooling system and a heat exchanger. The glycol loop traverses an ice bank in a multi-circuited fashion to increase the surface area and provide for maximum heat exchange at the ice interface. Such a configuration is efficient and works in concert with the heat exchanger in the system to enhance cooling capabilities. Such a design of an ice storage bin is flexible and could be configured to increase or decrease in size depending on the facility's needs.

An ice production and storage facility as used in at least one embodiment of the present disclosure generates reserve thermal capacity in the form of ice and then dispenses cooling through the chilled water loop when economical. This provides a number of benefits, including but not limited to: 1) the ICPS 200 can produce ice at night while power is less expensive with the added benefit that the chillers producing ice can be run at their optimum load; 2) ice can then be used during the hottest times of the day to cut the power costs of mechanical cooling, or in coordination with the utilities, provide a power shaving ability to both reduce operational costs and reduce the load on the power grid; and 3) the ice production and storage facility can be combined with and used to buffer the transitions between mechanical and other forms of free cooling, in order to produce a more linear cooling scheme where the cooling provided precisely meets the heat to be rejected, and thus driving down PUE.

To master control the envelope, in at least one embodiment of the present disclosure all components of and devices connected to the ICPS 200 are fully innervated with power quality metering and other forms of monitoring at the individual component level and whole systems level. Thus, an operator has accurate information on the status of the ICPS 200, as well as a view into the utility feed for certain electrical signatures (e.g., power sags and spikes, transmission problems, etc.), which may be used to predict anomalies. Ultimately, the information provided by these monitoring systems is fed into a GEOS 100 according to an embodiment of the present disclosure for analysis and decision-making. Hollowing both real-time and/or longitudinal analysis by GEOS 100, optimum parameters, which could include but are not limited to availability, reliability, physics, economics, and carbon footprint, are selected for the ICPS 200. At the electrical level, energy input source selection is accomplished at the level of the IESD. In the same way, thermal systems are balanced and sources selected through the dynamic modulation of systems producing thermal capacity.

### Distribution System for Balanced Electrical and Thermal Energy

At least one embodiment of the present disclosure contemplates a balanced system of electric and thermal energy sources. In addition to the energy source system, integral to the ICPS 200 according to at least one embodiment of the present disclosure is the distribution component of energy source model, which allows energy sources to be distributed between multi-building environment. In at least one such embodiment, this system integrates a four (4) pipe heat reclamation system and a diverse two (2) pipe electrical system. The purpose of such systems is to distribute redundant, reliable paths of electrical, thermal and fiber optic capacity. A benefit of an ICPS 200 according to at least one embodiment of the present disclosure is to offset energy consumption through the reutilization of secondary energy sources in a mixed use facility and/or a campus environment.

An ICPS 200 according to at least one embodiment of the present disclosure has a pre-cooling/heat reclamation loop system. Such a system is based on the principle of pre- and post-cooling, which allows the system to optimize heat transfer in an economizer operation cooling scenario. Even in the hottest weather, the ambient temperature is usually low enough that some of the heat produced by the data center can be rejected without resorting to 100% mechanical cooling. In this model, the “pre-cooling” is provided by a coil that is connected to a cooling tower or heat exchanger. That coil is used to “pre-cool” the heat-laden air, removing some of the heat before any mechanical cooling is applied. Any remaining heat is removed through primary cooling coils served by the ICPS 200 chiller system.

An additional benefit of pre-cooling is that it provides additional redundancy. If for some reason the primary cooling loop were to fail (a cut line, for example) the mechanical cooling could be re-routed via valving through the “pre-cooling” loop, providing an additional level of security and redundancy, In at least one embodiment, the cooling loops comprise a closed loop system to maximize the efficiency of the cooling fluid, avoid contamination found in open systems, and maintain continuous, regulated pressure throughout the system.

In at least one embodiment of the present disclosure, a series of closed loop cooling towers function to provide “free” cooling when outdoor ambient conditions are favorable and even with many towers, a close-coupled design allows each element of the thermal system to be engineered within close proximity. This cuts the distance between points of possible failure, and cuts cost by reducing components such as additional piping and valving.

Ultimately, the cooled water loops exit the ICPS 200 and, in at least one embodiment of the present disclosure, extend into the spokes of the hub and spoke model. In such an embodiment these water loops along with the power (distributed, in at least one embodiment of the present disclosure, at 12,470V) and fiber optic cables will be placed into at least one large diameter underground conduit per each point of final distribution (collectively referred to as the “distribution spoke”), and will arrive at a data center environment to be plugged into the necessary infrastructure, container, data center capsule 300, or other suitably equipped receiver for final distribution. The interface of the distribution spoke and the point of final distribution will be a docking station for whichever distribution element is designed to link to the ICPS 200. Such a hub and spoke design is intended to allow for multiple data center environments to be served by one ICPS 200, but other designs could be used, such as, for example, to accommodate operating conditions, terrain difficulties, or aesthetic concerns.

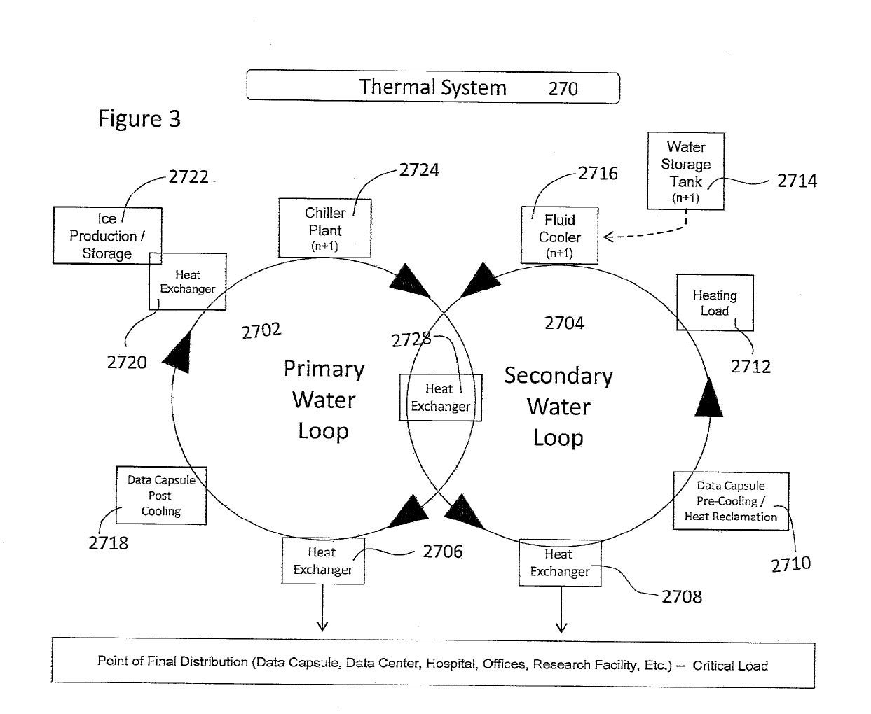

FIG. 3 shows a block diagram illustrating thermal system 270 of ICPS 200 according to at least one embodiment of the present disclosure, Shown in FIG. 3 are primary cooling loop 2702 and secondary cooling loop 2704. Both primary cooling loop 2702 and secondary cooling loop 2704 operate to remove heat from the point of final distribution such as, for example, a date center capsule 300 of the type disclosed herein.

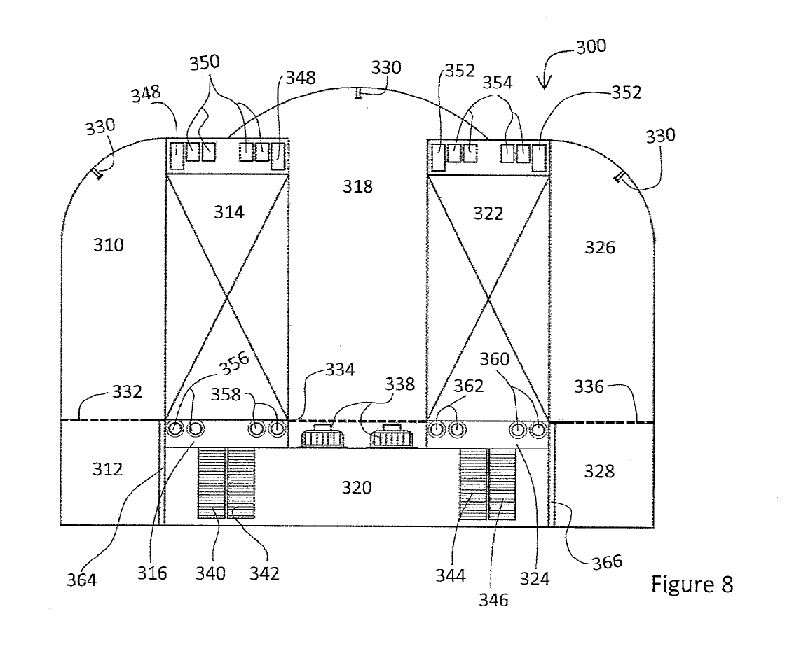

In the embodiment shown in FIG. 3, primary cooling loop 2702 interacts with the point of final distribution through heat exchanger 2706. In an embodiment where the point of final distribution is a data center capsule 300 such as the embodiment shown in FIG. 8, primary cooling loop 2702 includes left chilled fluid piping 358 and right chilled fluid piping 362, In an embodiment where the point of final distribution is a data center capsule 300 such as the embodiment shown in FIG. 8, heat exchanger 2706 comprises left primary cooling coil 342 and right primary coil 344.

In the embodiment shown in FIG. 3, primary cooling loop 2702 further comprises a two-way heat exchanger 2720 between primary cooling loop 2702 and an ice storage and production facility 2722, and a chiller plant 2724.

In the embodiment shown in FIG. 3, secondary cooling loop 2704 interacts with the point of final distribution through heat exchanger 2708. In an embodiment where the point of final distribution is a data center capsule 300 such as the embodiment shown in FIG. 8, secondary cooling loop 2704 includes left pre-cooling fluid piping 356 and right pre-cooling, fluid piping 360. In an embodiment where the point of final distribution is a data center capsule 300 such as the embodiment shown in FIG. 8, heat exchanger 2708 comprises left pre-cooling cooling coil 340 and right pre-cooling coil 346.

In the embodiment shown in FIG. 3, secondary cooling loop 2704 further comprises heating load 2712 and a fluid cooler 2716. Fluid cooler 2716 is interconnected with one or more water storage tanks 2714.

In at least one embodiment of a primary cooling loop 2702 and secondary cooling loop 2704, heat exchanger 2726 interconnects primary cooling loop 2702 and secondary cooling loop 2704.

### Data Center Capsule

One prior art attempt at scalable data centers is the “data center in a box” concept pioneered by a number of companies including APC, Bull, Dell, HP, IBM, Verari Technologies, SGI, and Sun Microsystems. This prior art approach is based on standard shipping containers for easy transportability and provides a self-contained, controlled environment. Within a 40-ft prior art container configuration, roughly 400 sq. ft. of traditional data center space is created through the placement of either standard 24″ wide, 42″ deep racks or custom designed rack configurations. Within a containerized data center environment ac cording to the prior art, maximum power densities can reach between 300-550 kW and between 500-1500 Us of computing capacity are available.

The containerized data center approach according to the prior art is limited in several ways: 1) space within a container can become a constraint, as data center customers expect their equipment to be readily accessible and serviceable; 2) in many cases, there is not a location or “landing zone” readily available with the appropriate power, thermal, and data connectivity infrastructure for the container itself and its power and thermal requirements; 3) the standard size shipping container was developed to meet requirements for ships, rail and trucks, and is not ideally suited to the size of computing equipment; custom components have to be developed to fit into the usable space and the thermal environment is difficult to control because of the configuration of the container itself; and power and thermal components are located either within, on top of, or adjacent to the prior art data containers so they either take up valuable computing space, or they require separate transport and additional space.

Data center capsule 300 according to the present disclosure incorporates novel elements to create a vendor neutral, open computing framework, and that offers space flexibility and meets the power and thermal density needs of present and future data center environments, and overcomes the shortcomings of the prior art. In conjunction with an ICPS 200 and GEOS 100 as disclosed herein, the data center capsule 300 according to the present disclosure is designed to be a point of final distribution for the power, thermal, and fiber optic systems. Concepts disclosed herein, in connection with the data center capsule 300 can also be utilized in a broad array of power and thermal management applications, such as, for example, modular clean rooms, modular greenhouses, modular medical facilities or modular cold storage containers.

A data center capsule 300 according to at least one embodiment of the present disclosure comprises 1) a lightweight, modular design based on a slide-out chassis; 2) internal laminar air-flow based on the design of the data center capsule 300 shell, supply fan matrix and positive air pressure control logic; 3) an integrated docking device (“IDD”), which couples the electric, thermal, and fiber optics to the data center capsule 300; 4) a pre/post fluid-based cooling system contained under the raised floor and integral to the capsule; 5) a matrix of variable speed fans embedded in the floor system designed to create a controlled positive pressure within the cold air plenum relative to hot containment zones; 6) placement of the compute within the cold air plenum; 7) autonomous, fully integrated control system; 8) fully integrated fire monitoring and suppression system; 9) integrated security and access control system; and 10) a humidity control system.

### Modular Construction

A data center capsule 300 according to at least one embodiment of the present disclosure is modular, such that multiple capsule sections can be joined together easily to accommodate expansion and growth of the customer. Electrical, thermal and data systems are engineered to be joined with quick-connects.

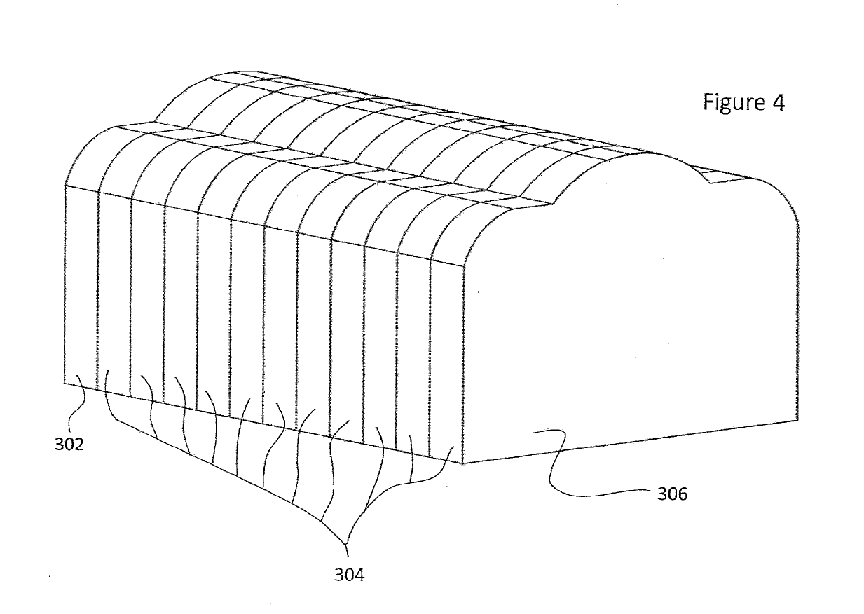

Shown in FIG. 4 is data center capsule 300 according to at least one embodiment of the present disclosure, comprising end modules 302 and 306 and a plurality of internal modules 304 According to at least one embodiment of the present disclosure each end module 302 and 306, and each internal module 304, comprises an individual section of the data center capsule 300. End module 302 and 306 and internal modules 304 are joined together with substantially air tight and water tight joints to form a data center capsule 300.

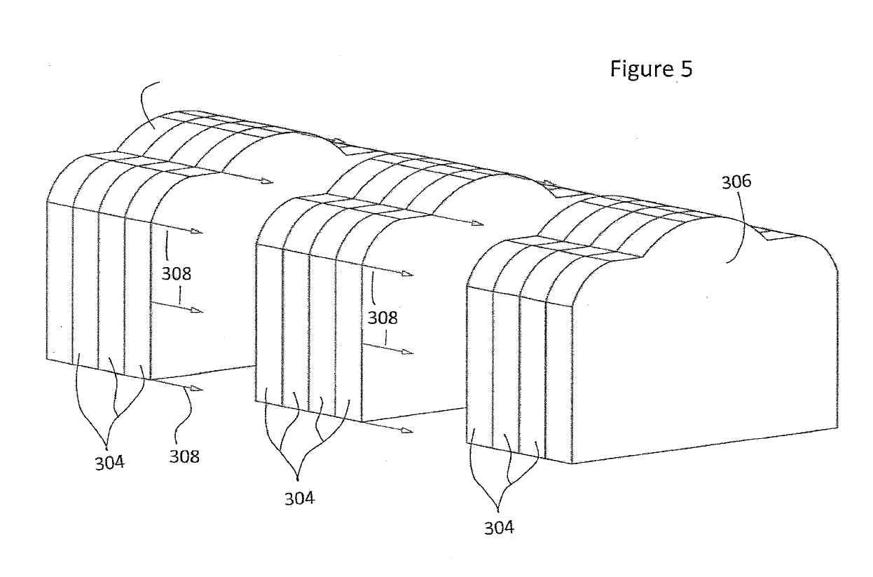

Shown in FIG. 5 is a partially exploded view of data center capsule 300 according to at least one embodiment of the present disclosure, illustrating the modular design of data center capsule 300. Shown in FIG. 5 are end modules 302 and 306, and a plurality of internal modules 304. As shown in FIG. 5, internal modules 304 are joined together as shown by arrows 308. Accordingly, data center capsule 300 may be configured to be any desired length by adding additional internal modules 304 to meet the needs of a particular deployment thereof.

In at least one embodiment of the present disclosure, each such capsule section or module is designed to be assembled on-site from its constituent components, which could include:
Upper left hot aisle
Lower left hot plenum with filter section
Upper left four-rack assembly with power bus
Lower left rack support tub with cooling coils and piping
Upper central cold aisle
Lower central cold aisle tub with fans
Upper right four-rack assembly with power bus
Lower right rack support tub with cooling coils and piping
Upper right hot aisle
Lower right hot plenum with filter section

It is intended that all module components as described above can be readily conveyed within most standard size freight elevators and doorways and assembled on site.

### Interior Design

The prior art containerized data center has limited space due to the size constraints of a standard shipping container. This results in a very cramped environment which impedes movement within the space, and creates difficulty in accessing and servicing the compute equipment. In some prior art solutions, access to the rear of the compute equipment is accomplished from the conditioned cold aisle which results in reduced cooling performance due to air recirculation through the equipment access void(s). In one embodiment of the present disclosure, the data center capsule 300 is designed to replicate the aisle spacing prevalent in the traditional data center environment, and affords unrestricted access to the front and rear of all installed compute equipment. Hot aisle width in such an embodiment is in the range of 30 to 48 inches, and cold aisle width in such an embodiment is in the range of 42 to 72 inches.

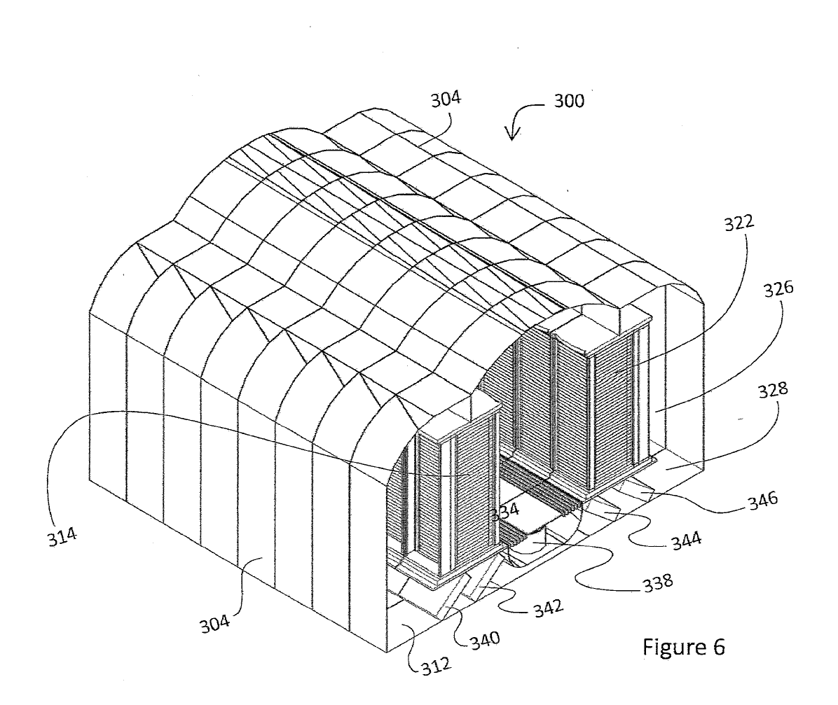

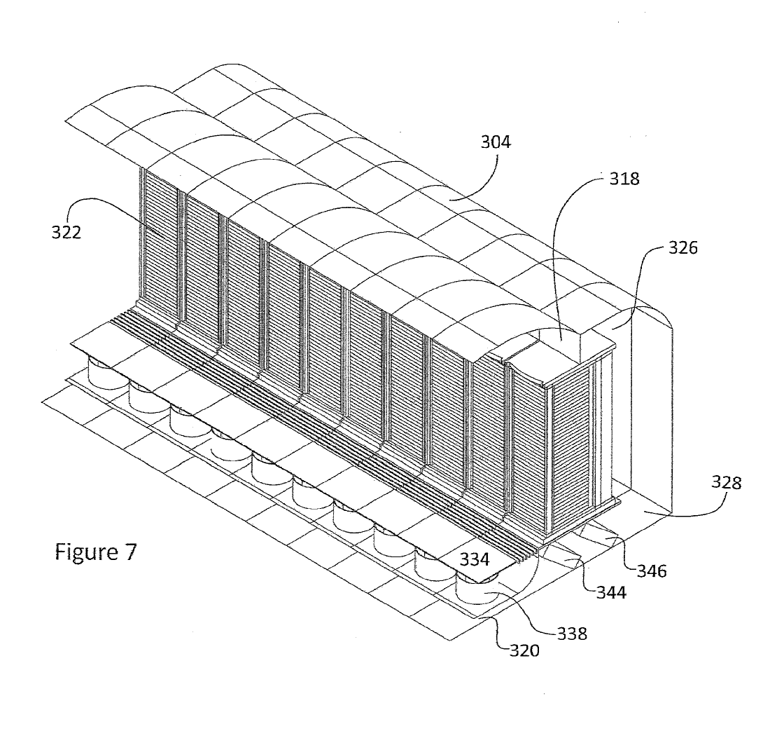

FIG. 6 shows a partially cutaway perspective view of a data center capsule 300 according to at least one embodiment of the present disclosure. FIG. 7 shows a partially cutaway perspective view of a data center capsule 300 according to at least one embodiment of the present disclosure. FIG. 8 shows a cutaway elevation view of a data center capsule 300 according to at least one embodiment of the present disclosure.

Shown in FIGS. 6-8 are upper left but aisle 310, lower left hot plenum 312 including filter 364, left rack assembly 314, left rack support tub 316 including left pre-cooling fluid piping 356 and left chilled fluid piping 358, upper central cold aisle 318, lower central cold aisle 320 including left pre-cooling coil 340, left primary cooling coil 342, right primary coil 344 and right pre-cooling coil 346, right rack assembly 322, lower right rack support tub 324 including right pre-cooling fluid piping 360 and right chilled fluid piping 362, upper right hot aisle 326, lower right hot plenum 328 including filter 366, fire suppression system 330, left perforated floor 332, central perforated floor 334, right perforated floor 336, fans 338, left fiber and cable trays 348, left electrical busses 350, right fiber and cable trays 352, and right electrical busses 354.

### Lightweight Frame and Slide-Out Chassis

In traditional brick-and-mortar data centers, consulting engineers design structures to support heavy loads of up to 300 lbs. per square foot, contributing to increasing costs that have driven the expense of building data centers in many cases to the $3000 per square foot range. A data center capsule 300 according to at least one embodiment of the present disclosure is designed with lightweight materials that can be deployed in traditional commercial spaces that are designed to support between 100-150 lbs. per sq. foot of critical load is ideally positioned to meet the needs of cost conscious-data center and corporate owners. The value of this lightweight solution is readily apparent in locations such as high-rise buildings, where structural load is a critical element to the buildings infrastructure and ultimately commercial capabilities.

In addition to light weight, the slide-out chassis design according to at least one embodiment of the present disclosure will allow technicians to work on the cabinets in the same manner as afforded in traditionally built data center environments, while all of the mechanical and electrical components are accessible from the exterior of the data center capsule 300. When in place, the data center capsule 300 has the ability to expand along its length to provide sufficient space to move between the racks, similar to a traditional cold and hot aisle configuration. In order to be moved, the rows of cabinets could be slid together and locked, providing for easy transportability that would fit on trucks or railcars. This slide-out design features standard ISO-certified lifting lugs at critical corner points to enable hoisting through existing crane technologies. By today's standards, a fully-loaded (complete with servers, racks, etc.) conex-based containerized data center according to the prior art weighs between 90,000-115,000 lbs. The data center capsule 300 according to the present disclosure is produced from a variety of materials including steel, aluminum, or composites greatly reducing the weight of the self-contained system, facilitating both its transport and installation.

### Laminar Air-Flow Design

Removing heat from a compute environment is a primary focus of any data center design. Although several choices exist, one possible solution is to transfer the heat into a cooling fluid (i.e. air, water, etc.), remove the cooling fluid from the compute environment, and reject the excess heat either mechanically or through free cooling. According to at least one embodiment of the present disclosure, the roof/ceiling design of a data center capsule 300 is designed to enhance the circulation efficiency of air within a limited amount of space. Such a design achieves a slight over pressure in the cold aisle with a uniform, laminar flow of the cooling fluid. In at least one embodiment, uniform volume of cooling fluid creates an enhanced condition for server utilization of the cooling fluid. In at least one embodiment of the present disclosure, the servers within data center capsule 300 utilize internal fans to draw only the amount of cooling fluid necessary to satisfy their internal processor temperature requirements. Ultimately, though utilization of laminar flow, a positive cold volume of cooling fluid is drawn through the devices and their controls in a variable manner. This allows for self-balancing of cooling fluid based on need of the individual server(s), which have a dynamic range of power demands. The purpose is to produce the highest value of secondary energy source by allowing the servers to produce consistently high hot aisle temperatures.

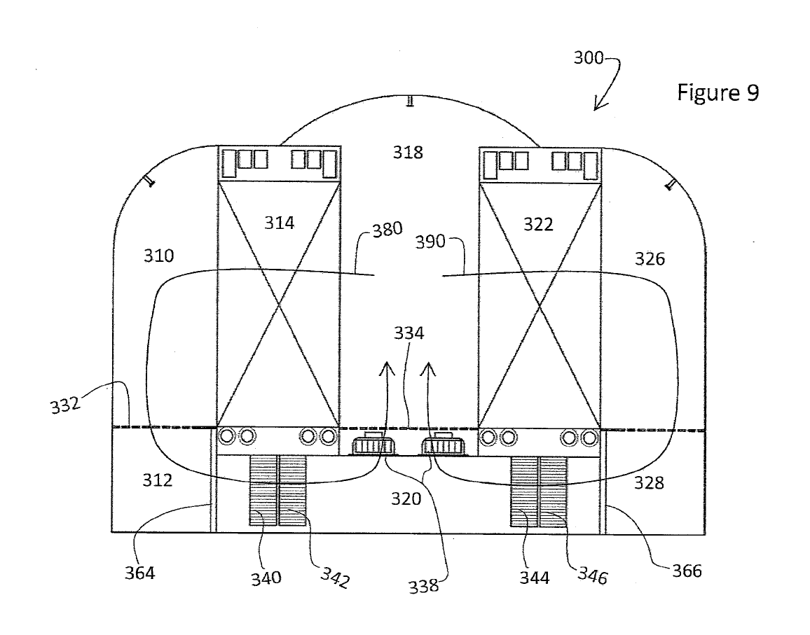

FIG. 9 shows a cutaway elevation view of a data center capsule 300 according to at least one embodiment of the present disclosure, illustrating the flow of cooling fluid such as air through data center capsule 300. Cooling fluid flow is shown by arrows 380 and 390 in FIG. 9. As shown in FIG. 9, fans 338 create a position pressure in upper central cold aisle 318, forcing cooling fluid through left rack assembly 314 and right rack assembly 322. Heat is absorbed from the equipment in left rack assembly 314 and right rack assembly 322. The heated fluid flows into upper left hot aisle 310 and upper right hot aisle 326, through left perforated floor 332 and right perforated floor 336, and through lower left hot plenum 312 and filter 364 and lower right hot plenum 328 and filter 366. The heated fluid then flows into lower central cold aisle 320 and over left pre-cooling coil 340, left primary cooling coil 342, right pre-cooling coil 346, and right primary coil 344, where it is cooled. The cooled fluid then is forced by fans 338 through central perforated floor 334 and back into central cold aisle 318.

### Integrated Docking Device (IDD)

To provide a link from an ICPS 200 to a data center capsule 300 in at least one embodiment of the present disclosure, an integrated docking device (“IDD”) equipped with a series of ports is deployed. In at least one embodiment of the present disclosure, at least two ports will house links to a redundant chilled water loop. In at least one embodiment of the present disclosure, at least two ports will house the links to the redundant fiber connection into each capsule. In at least one embodiment of the present disclosure, at least two ports will interface with an electrical transformer to convert the high potential power being feed to the IDD at 12,470V or 13,800V to a voltage useable by for the data center capsule 300 environment. In at least one embodiment of the present disclosure, each data center capsule 300 according to the present disclosure may be prewired to accommodate multiple voltages and both primary and secondary power.

### Pre/Post Cooling

Within a data center capsule 300 according to at least one embodiment of the present disclosure, a pre/post cooling system is located under the data rack system. In at least one embodiment of the present disclosure, a pre-cooling coil integrated in this system is intended to be a “secondary energy transfer device.” This energy transfer device functions to capture the thermal energy produced by the server fan exhaust. The intention of this energy capture is to reutilize the waste heat from the servers in a variety of processed heating applications, such as radiant floor heat, preheating of domestic hot water, and/or hydronic heating applications.

In at least one embodiment of the present disclosure, a post cooling coil is intended to function in a more traditional manner to provide heat transfer to the cooling fluid. In this way, the efficient transfer and subsequent utilization of heat allows the system to utilize what is normally exhausted energy. In this way, the pre-cooling coil provides a “first-pass” cooling that reduces the air temperature considerably. This relieves the load on the second coil, which utilizes more expensive mechanical cooling, thus improving PUB. According to at least one embodiment of the present disclosure, such coils confer consistent temperature, while fans are separately responsible for maintaining air pressure. According to at least one embodiment of the present disclosure, there is no direct mechanical, electrical or logical linkage between the coils and the fans.

This streamlined design allows the coils to maintain constant temperature based on algorithmic and/or operator-programmed set points. Through the disassociation of the coils from the air-handler, the data center capsule 300 according to at least one embodiment of the present disclosure is capable of decreasing PUE. A data center capsule 300 according to at least one embodiment of the present disclosure comprising a 2-coil cooling system utilizes linear cooling that relieves the need to mechanically cool and move large volumes of air and enables the two coils to utilize free-cooling whenever possible to eliminate heat and produce more economical utilization of power. As an added bonus, in at least one embodiment, either coil can be used for mechanical cooling, providing a built in N+1 architecture in case of coil or piping failure,

### Variable Speed Fan Matrix

According to at least one embodiment of the present disclosure, fan technology is a component of the overall design and functionality of a data center capsule 300. In at least one embodiment of the present disclosure, to create an over-pressure cold air plenum, a specialized matrix of variable speed fans embedded in the raised floor of a data center capsule 300 and two-coil cooling system are utilized. A variable-speed fan matrix is disassociated from cooling coils and functions solely to maintain a substantially constant pressure within the data center capsule 300 plenum. In addition to the fans, a specialized angle diffusion grid may be utilized to direct air movement in front of the server racks. By varying the angle and velocity of air diffusion through the grid, the operator has the ability to control placement of the cold air volume in front of the servers. Although placement of cold air is one variable, the purpose of the fan matrix and control systems is to control the pressure of the cold-volume of cooling fluid on the front face of the servers. In this way, pressure is the controlling element and thus enables a uniform volume of cooling fluid for server consumption. The matrix of fans will be designed in an N+1 redundant configuration. Each such fan is equipped with an ECM motor with integrated variable speed capability. E ach such fan will have the capability of being swapped out during normal operations through an electrical and control system quick-connect fitting. The fans maintain a pressure set point and the coils maintain a set temperature to meet the cooling needs of the data center capsule 300. Although the data center capsule 300 shell will provide flexibility in cooling system design, in at least one embodiment of the present disclosure, air is the cooling fluid moving across the servers and related electronics. Utilizing air as the main cooling fluid has several advantages, including but not limited to, that the fans maintain a constant pressure and maintaining a slight positive air pressure in the cold section allows the it equipment to self-regulate their own, independent and specific cooling requirements. This “passive” system allows for less energy use while providing great cooling efficiencies. By contrast, liquid cooled systems require water to be moved around the compute environment, which is risky with customer's high value data on the line. Through this design the fans within the servers/computers are able to draw cold air as needed from a slightly over-pressured environment rather than forcing unneeded air volumes through the compute. In a data center capsule 300 according to the present disclosure, fans within the data center capsule 300 and the servers/computers work in concert to optimize the flow of cold air, utilizing physics only with no mechanical or logical connection between them.

### Compute Within the Air Handler

In at least one embodiment of a data center capsule 300 according to the present disclosure, the computing equipment is placed within a positive-pressured, cold-air plenum. In this design, the Interior of the data center capsule 300 becomes a cold air plenum with the compute contained within the air handler itself, Each data center capsule 300 according to at least one embodiment of the present disclosure contains eight to twenty four standard size cabinets facing each other in pairs, with the face (cool side) of the servers facing in, and the back (hot side) facing out. This design eliminates the need for an internal air duct system. In essence, the computing equipment is placed within the air-handling unit, rather than the air handling unit having to pressurize the air externally to fill a plenum and/or duct to convey the air to the computing devices.

### Integrated Control System

To integrate control of the diverse power, thermal, and security systems within a data center capsule 300 according to the present disclosure, a physical connection to a data network is made possible through a network control device such as, for example, the Honeywell/Tridium Java Application Control Engine or JACE. By utilizing this approach, network protocols such as LonWorks, BACnet, oBIX, and Modbus may be utilized to manage the power, thermal, security systems within a data center capsule 300 or among a system of data center capsules 300. In at least one embodiment of the present disclosure, after each data center capsule 300 is powered and connected to a fiber optic network, each data center capsule 300 may self-register through the JACE to the master network controlled by a GEOS 100, thus enabling the control of a system of data center capsules 300 through a centralized platform. In a stand-alone environment, the JACE provides a web interface from which the entire data center capsule 300 environment could be monitored and controlled.

### Integrated Fire Suppression System

A data center capsule 300 according to the present disclosure may be deployed with a complete double-interlock, pre-action fire detection and suppression system comprised of a very early warning smoke detection solution, such as the VESDA system by Xtralis, and a Hi-Fog water mist suppression system by Marioff. Such a fire suppression system can be completely stand-alone, or served by a pre-existing fire pump system within the environment containing the capsule.

### Global Energy Operating System (GEOS)

Managing the energy use in commercial and residential buildings has become a major focus over the last 10 years as the price for fossil fuels has risen and competition for limited resources has increased. There are a number of Building Automation Systems that provide the ability to monitor and control the HVAC and electrical systems of buildings. Similarly, most commercial buildings have some form of electronic access control or security. Finally, a number of companies are developing the means of monitoring the electrical consumption of computing devices and other electronic equipment.

However, while there has been progress on integrating various control systems including, but not limited to, HVAC and electrical, to date these efforts have been largely proprietary. Final integration happens only at the user level, and/or there is a great deal of manual mapping to make the different systems work together. In addition, each individual system is expensive and combining them into integrated systems compounds the expense. Finally, the analytics that are generally provided are usually non-integrated (they don't analyze multiple systems and types of systems at the same time, i.e. thermal and electrical), are reactive rather than predictive (they can tell you what happened, not what will or might happen), and require human interpretation to draw conclusions and then make the necessary control changes.

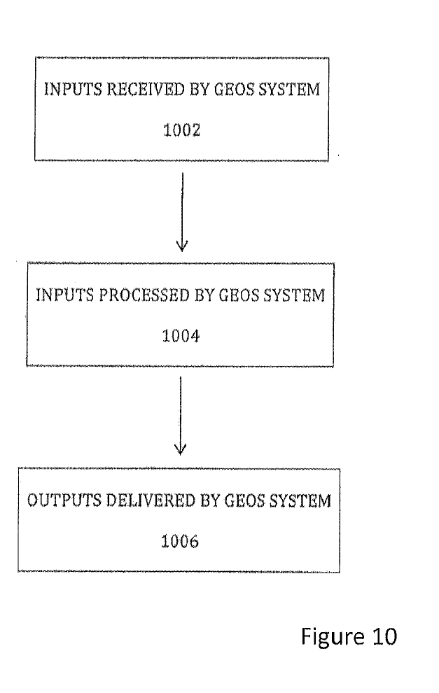

FIG. 10 shows a flowchart illustration the operation of a global energy operating system such as GEOS 100, according to at least one embodiment of the present disclosure. GEOS 100 is a software application that, in at least one embodiment of the present disclosure, utilizes artificial intelligence along with advanced data modeling, data mining, and visualization technology and serves as the analytic engine and master controller of the physical components of the systems disclosed herein, including the integrated central power system and its electrical/thermal/data connectivity transmission system, and data center environments such as the data center capsule 300 disclosed herein. Within the context of the systems for balanced power and thermal management of mission critical environments according to the present disclosure, GEOS 100 will collect data from the entire energy and security envelope, including generation, transmission, distribution, and consumption, learn as it performs its functions, and leverage information from multiple mission critical environments to effectively and efficiently control the environment. Inputs to GEOS 100 will come from multiple sensor and controller networks. These networks, which could be found within a building, the ICPS 200, the data center capsule 300, or any other structure equipped with this technology, will serve as a dynamic feedback loop for GEOS 100. In one embodiment, information such as ambient air temperature, relative humidity, wind speed or other environmental factors, power purchase rates, transmission or distribution power quality, central plant water temperature, or factors in the data center capsule 300 such as fan speeds, pressure and temperature values, could all be fed into the GEOS 100 to dynamically model the ICPS 200, transmission system, and data capsule to produce the optimum environment modeled for availability, reliability, physics, economics, and carbon footprint. Collectively these factors are intended to modeled and analyzed Within the GEOS 100. Ultimately, local control, is achieved both by real-time data analysis at the individual end-point, but also as a function of the larger analysis done by GEOS 100 and then subsequently, pushed out to the control end points to further refine the control strategy.

In at least one embodiment, GEOS 100 incorporates information from each building or site's thermal, electrical, security, and fire protection systems. In addition, it incorporates information on critical loads (the computers in a data center, for instance) and allows the input of economic and financial data, including, but not limited to the current rate per kilowatt-hour of electricity and cost per therm of natural gas. Such data is collected through an open and scalable collection mechanism, The data collected is then aggregated, correlations drawn between the various data from the diverse systems and locations, and the resultant data set analyzed for the core drivers of availability, reliability, physics, economics, and carbon footprint Such an analysis will make use of various forms of data mining, machine learning techniques, and artificial intelligence to utilize the data for real time control and more effective human analysis. The interplay of the core drivers is important for local real-time decision making within the system. These factors have the capability to then again be analyzed longitudinally across multiple data sets, such as archived data points including, but not limited to detailed building information or information from data center capsules, external data sets including, but not limited to weather bin data, national electrical grid data, carbon emission surveys, USGS survey data, seismic surveys, astronomical, or other data sets collected on natural phenornenon or other sources to produce a higher level of analysis that can be utilized to prioritize the core drivers. In addition, in at least one embodiment the data will be “research grade” and thus a product in and of itself, available to those interested in utilizing the data.

In at least one embodiment of the present disclosure, GEOS 100 will communicate with many building control systems, including OBIX, BacNET, Modbus, Lon, and the like, along with new and emerging energy measurement standards. In at least one embodiment of the present disclosure, GEOS 100 will comprise an open, layered architecture that will be as stateless as possible and utilize standard protocols, facilitating intercommunication with other systems. In at least one embodiment of the present disclosure, GEOS 100 will store, process, and analyze vast amounts of data rapidly, and as a result it will likely be necessary to use advanced storage and analysis techniques, along with specialized languages to facilitate performance and reliability.

After being presented with the disclosure herein, one of ordinary skill in the art will realize that the embodiments of GEOS 100 can be implemented in hardware, software, firmware, and/or a combination thereof. Programming code according to the embodiments can be implemented in any viable programming language such as C, C++, XHTML, AJAX, JAVA or any other viable high-level programming language, or a combination of a high-level programming language and a lower level programming language.

While this disclosure has been described as having a preferred design, the systems and methods according to the present disclosure can be further modified within the scope and spirit of this disclosure. This application is therefore intended to cover any variations, uses, or adaptations of the disclosure using its general principles. For example, the methods disclosed herein and in the appended claims represent one possible sequence of performing the steps thereof. A practitioner may determine in a particular implementation that a plurality of steps of one or more of the disclosed methods may be combinable, or that a different sequence of steps may be employed to accomplish the same results. Each such implementation falls within the scope of the present disclosure as disclosed herein and in the appended claims. Furthermore, this application is intended to cover such departures from the present disclosure as come within known or customary practice in the art to which this disclosure pertains and which fall within the limits of the appended claims.

1-57. (canceled)

58. A data center capsule, the data center capsule comprising:
a first data center module, the first data center module comprising:
a pre-cooling system;
a post-cooling system;
a network system; and
an electrical system.

59. The data center capsule of claim 58, further comprising:
a second data center module joined to the first data center module, the second data center module comprising:
a cooling system; and
an electrical system.

60. The data center capsule of claim 59, wherein at least one of the first data center module and the second data center module further comprises a data and control network.

61. The data center capsule of claim 59, wherein the first data center module and the second data center module are joined air-tightly.

62. The data center capsule of claim 59, wherein the first data center module and the second data center module are joined water-tightly.

63. The data center capsule of claim 59, wherein the first data center module's cooling system is coupled to the second data center module's cooling system.

64. The data center capsule of claim 59, wherein the first data center module's electrical system is coupled to the second data center module's electrical system.

65. The data center capsule of claim 60, wherein the first data center module further comprises a data and control network, and wherein the first data center module's data network is communicatively coupled to the second data center module's data and control network.

66. The data center capsule of claim 58, wherein the first data center module further comprises an integrated docking device.

67. The data center capsule of claim 59, further comprising:
a computer-based system for controlling the energy- and/or thermal-envelope of a data center, the computer-based system communicatively coupled to the first data center module and the second data center module.

68. A modular power system comprising:
power distribution circuitry;
fiber optic data cable circuitry; and
chilled water plumbing.

69. The modular power system of claim 68, further comprising:
an energy selection device capable of switching between multiple electric energy sources as needed within one quarter cycle.

70. The modular power system of claim 69, further comprising:
a step-down transformation system that converts an input voltage of at least 12,470 volts to an output voltage of 208 volts or 480 volts.

71. The modular power system of claim 69, further comprising:
a water chilling plant.

72. The modular power system of claim 69, further comprising:
a thermal storage facility that stores excess thermal capacity in the form of ice or water, the thermal storage facility being equipped with a glycol cooling exchange loop, a heat exchanger, and ice producing chiller plant or comparable ice-producing alternative.

73. The modular power system of claim 69, further comprising:
a system of cooling loops, which may comprise multi-path chilled water loops, a glycol loop for the ice storage system, and a multi-path cooling tower water loop.

74. The modular power system of claim 69, further comprising:
a thermal input selection device.

75. The modular power system of claim 69, further comprising:
a heat recovery system comprising a primary water loop, the heat recovery system providing pre-cooling and heat reclamation.

76. The modular power system of claim 69, further comprising:
a plurality of cooling systems arranged in an N+1 configuration.

77. The modular power system of claim 69, further comprising:
a computer-based system for controlling the energy- and/or thermal-envelope of a data center, the computer-based system communicatively coupled to the modular power system.

78. A data center, the data center comprising:
a first data center module, the first data center module comprising a first cooling system, a first electrical system, a first data and control network, and an integrated docking device;
a second data center module joined to the first data center module, the second data center module comprising a second cooling system, a second electrical system, and a second data and control network, wherein the first cooling system is coupled to the second cooling system, the first electrical system is coupled to the second electrical system, and the first data and control network is communicatively coupled to the second data and control network; and
a modular power system, the modular power system comprising power distribution circuitry, fiber optic data cable circuitry, chilled water plumbing, an energy selection device capable of switching between multiple electric energy sources as needed within one quarter cycle, and a transformation system that converts an input voltage of at least 12,470 volts to an output voltage of at least 208 volts or 480 volts,
wherein the integrated docking device comprises a first connector configured to connect the first electrical system to the power distribution circuitry, a second connector configured to connect the first cooling system to the chilled water plumbing, and a third connector configured to connect the first data and control network to the fiber optic data cable circuitry; and
a computer-based system for controlling the energy- and/or thermal-envelope of a data center, the computer-based system communicatively coupled to the first data center module, the second data center module, and the modular power system.
